(19) United States
(12) Patent Application Publication
(10) Pub. No.: US 2023/0409786 A1
(43) Pub. Date: Dec. 21, 2023

(54) RECORDING MEDIUM, DESIGN AIDING METHOD, AND INFORMATION PROCESSING DEVICE

(71) Applicant: Fujitsu Limited, Kawasaki-shi (JP)

(72) Inventors: Hitomi KOBAYASHI, Numazu (JP); Akio IWATA, Gotemba (JP)

(73) Assignee: Fujitsu Limited, Kawasaki-shi (JP)

(21) Appl. No.: 18/170,777

(22) Filed: Feb. 17, 2023

(30) Foreign Application Priority Data
Jun. 15, 2022 (JP) 2022-096899

(51) Int. Cl. G06F 30/31

(52) U.S. Cl. CPC G06F 30/31

(57) ABSTRACT

A computer-readable recording medium stores therein a design aiding program that aids layout design of a circuit under design and that is executable by a computer, the design aiding program includes: an instruction for disposing a plurality of cells in a layout of the circuit under design, based on circuit information related to the circuit under design; and an instruction for determining, for two adjacent cells of the cells disposed in the layout, a disposal number and disposal positions of cut metals to be disposed between the two adjacent cells, based on lengths of branch wires in each of the two adjacent cells and a type of a wire that includes the branch wires, each of the lengths being between a via and a cell frame of said each of the two adjacent cells, the via being on the wire in the two adjacent cells.

### CROSS REFERENCE TO RELATED APPLICATIONS

This application is based upon and claims the benefit of priority of the prior Japanese Patent Application No. 2022-096899, filed on Jun. 15, 2022, the entire contents of which are incorporated herein by reference.

### FIELD OF THE INVENTION

The embodiments discussed herein are related to a recording medium, a design aiding method, and an information processing device.

### BACKGROUND OF THE INVENTION

A multi-patterning technique such as self-aligned double patterning (SADP) has been used as a process technology for high density wiring. According to the multi-patterning technique, a metal wire spread over a wiring channel is divided and used for wire connection. The division of the metal wire is executed by, for example, disposing a recognition layer (a cut metal) to separate the metal wire on a computer aided design (CAD).

For example, a technique to design a semiconductor integrated circuit having a fin field effect transistor (finFET) structure is present as a prior art. A technique to determine a wire pattern to remove cross talk noise is present. According to another technique, a wire pattern to connect a group of terminals is generated in a wiring layer based on the disposition of cells, a wiring prohibited region is removed in a case where the wire pattern extends into the wiring prohibited region, and correction of the wire pattern arising from the removal of the wiring prohibited region is executed. A semiconductor device is present that includes an open pattern in which an extension wiring layer is separated into gate wiring constituting a gate electrode of a transistor in an active region and dummy wiring not constituting a gate electrode in an element isolating area. For examples, refer to Japanese Laid-Open Patent Publication No. 2014-010839, Japanese Laid-Open Patent Publication No. 2004-171363, Japanese Laid-Open Patent Publication No. 2002-353314, and Japanese Laid-Open Patent Publication No. 2013-157498.

### SUMMARY OF THE INVENTION

According to an aspect of an embodiment, a computer-readable recording medium stores therein a design aiding program that aids layout design of a circuit under design and that is executable by a computer, the design aiding program includes: an instruction for disposing a plurality of cells in a layout of the circuit under design, based on circuit information related to the circuit under design; and an instruction for determining, for two adjacent cells of the cells disposed in the layout, a disposal number and disposal positions of cut metals to be disposed between the two adjacent cells, based on lengths of branch wires in each of the two adjacent cells and a type of a wire that includes the branch wires, each of the lengths being between a via and a cell frame of said each of the two adjacent cells, the via being on the wire in the two adjacent cells.

An object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram depicting one example of a design aiding method according to a first embodiment.

FIG. 2 is an explanatory diagram depicting one example of a standard cell having cut metals disposed on a cell frame thereof.

FIG. 3 is an explanatory diagram depicting an example of an error occurring in a case where cut metals are disposed at feet of vias.

FIG. 4 is an explanatory diagram depicting one example of the standard cell that has no cut metal disposed on the cell frame thereof.

FIG. 5 is an explanatory diagram depicting an example of a system configuration of an information process system 500.

FIG. 6 is a block diagram depicting an example of a hardware configuration of a circuit designing device 501.

FIG. 7 is a block diagram depicting an example of a functional configuration of the circuit designing device 501.

FIG. 8 is an explanatory diagram depicting an example of obtaining a length of a branch wire.

FIG. 9 is an explanatory diagrams depicting an example of setting of a degree of priority of the branch wire.

FIG. 10 is an explanatory diagrams depicting an example of the setting of the degree of priority of the branch wire.

FIG. 11 is an explanatory diagrams depicting an example of the setting of the degree of priority of the branch wire.

FIG. 12 is an explanatory diagrams depicting an example of the setting of the degree of priority of the branch wire.

FIG. 13 is an explanatory diagrams depicting an example of the setting of the degree of priority of the branch wire.

FIG. 14 is an explanatory diagrams depicting an example of the setting of the degree of priority of the branch wire.

FIG. 15 is an explanatory diagram depicting an example of setting of positioning information.

FIG. 16 is an explanatory diagram depicting an example of a data structure of the positioning information.

FIG. 17 is an explanatory diagram depicting an example of determination of a disposal number of cut metal.

FIG. 18 is an explanatory diagram depicting an example of determination of disposal positions of the cut metals.

FIG. 19 is an explanatory diagram depicting an example of occurrence of a space error between the cut metals.

FIG. 20 is an explanatory diagram depicting an example of correction of the disposal positions of the cut metals.

FIG. 21 is a flowchart depicting one example of a procedure for a preparation process by the circuit designing device 501.

FIG. 22 is a flowchart depicting one example of details of a process procedure for a positioning information setting process.

FIG. 23 is a flowchart depicting one example of details of the process procedure for the positioning information setting process.

FIG. 24 is a flowchart depicting one example of a procedure for a circuit design process by the circuit designing device 501.

FIG. 25 is a flowchart depicting one example of details of a process procedure for a cut metal disposition process.

FIG. 26 is a flowchart depicting one example of details of a process procedure for a determination process.

FIG. 27 is a flowchart depicting one example of details of a process procedure for a space error correction process.

### DESCRIPTION OF THE INVENTION

First, problems associated with the conventional techniques are discussed. With the conventional techniques, a problem arises that an inter-wire capacitance (a parasitic capacitance) is increased by wiring not used for wire connections (branch wires) in the layout design using the multi-patterning technique.

Embodiments of the present invention described in detail with reference to the accompanying drawings.

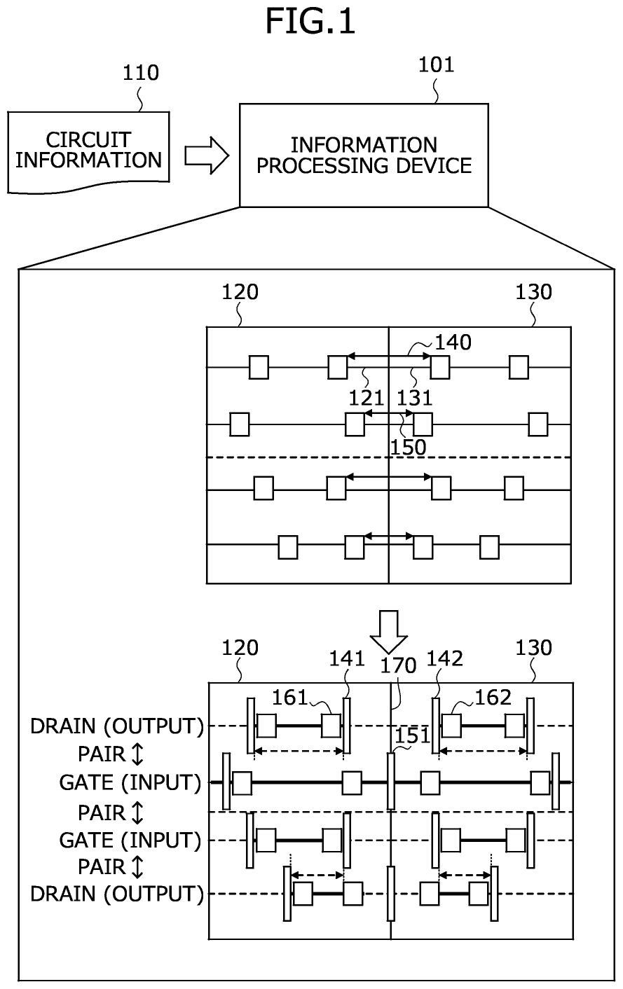

FIG. 1 is an explanatory diagram depicting one example of a design aiding method according to a first embodiment. In FIG. 1, an information processing device 101 is a computer that aids layout designing for a circuit under design. The circuit under design is a semiconductor integrated circuit such as, for example, a central processing unit (CPU), a graphics processing unit (GPU), or a memory.

In the multi-patterning technique, different from a method of drawing a figure of metal wires necessary for wire connections, wire portions obtained by dividing a metal wire spread over a wire channel are used in the wire connections. To divide the wire spread over the wire channel for different signals, a recognition layer that is to separate the metal wire and referred to as “cut metal” is disposed on a CAD.

A layout of a macro is executed by preparing standard cells, disposing the standard cells to match a circuit, and wiring (connecting) the standard cells. The macro is a circuit to realize a specific function (such as, for example, calculation or counting). The standard cell is a cell constituting a basic part of the circuit and is, for example, a logic gate such as an AND or a NAND, a buffer, a flipflop, a multiplexer, etc.

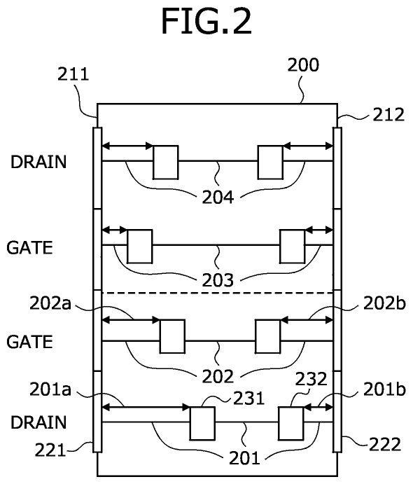

At this time, to separate signals from each other between adjacent cells, a cut metal may be disposed. It may be considered, for example, that a cut metal is disposed in advance on a cell frame of each cell (see, for example, FIG. 2 described later). The cell frame is a portion that borders the periphery of a cell and is, for example, a portion in contact with an adjacent cell in a lateral direction (wire direction).

In this case, when the cells are disposed, the cut metals each on a cell frame form one cut metal by overlapping each other on the cell frames in a border portion of the cells adjacent to each other, and no space error occurs. The space error is one of multiple errors defined in design rules, and is an error caused by a distance between the cut metals being too short.

In the case of a standard cell whose cell frame has a cut metal disposed thereon, a problem arises that inter-wire capacitance is increased by a metal wire not used in wire connection. The wires in the standard cell include, for example, a gate wire, a drain wire, an internal wire, and a floating wire. The drain wire is a signal wire on the output side. The gate wire is a signal wire on the input side. The internal wire is a signal wire other than the drain wire and the gate wire. The floating wire is a wire portion that is not used as a signal wire.

It is known that, at a point at which a gate wire and a drain wire are adjacent to each other, the polarities are opposite to each other, whereby the inter-wire capacitance is amplified, and the inter-wire capacitance seems to be larger than actually is. This action is referred to as “Miller effect”. The influence of the Miller effect is proportional to the adjacency length between the gate wire and the drain wire, increases the inter-wire capacitance, and causes a delay and electric power degradation.

A wire generated using the multi-patterning technique is an extension wire. In the case of a standard cell having cut metals disposed on the cell frame thereof, a wire not used in the wire connection is present between a via (VIA) and the cell frame. A via is a connection area (a component) to connect between wires each in a different layer.

In the following description, a wire present between a via and a cell frame may be denoted as “branch wire”. A standard cell having cut metals disposed on the cell frame thereof is described with reference to FIG. 2.

FIG. 2 is an explanatory diagram depicting one example of the standard cell having cut metals disposed on the cell frame thereof. In FIG. 2, a cell 200 is one example of the standard cell having cut metals disposed on the cell frame thereof. The cell 200 includes wires (extension wires) 201 to 204. The wires 201 and 204 are drain wires. The wires 202 and 203 are gate wires.

Vias are disposed on the wires 201 to 204. For example, on the wire 201, vias 231 and 232 are disposed. On cell frames 211 and 212 of the cell 200, for example, cut metals 221 and 222 are disposed.

In this case, when the cell 200 is disposed, signals may be separated between the cell 200 and an adjacent cell by the cut metals 221 and 222. The cut metals 221 and 222 each overlap on a cut metal present on the cell frame of the adjacent cell and an occurrence of the space error may thereby be prevented.

In the cell 200, however, branch wires not used in the wire connection are present. For example, on the wire 201, branch wires 201a and 201b are present. On the wire 202, branch wires 202a and 202b are present. In the cell 200, the branch wire is added to the metal wire used in the wire connection resulting in a wire that is longer than necessary and thus, the inter-wire capacitance increases.

In particular, between a gate wire and a drain wire like between the wires 201 and 202, and between the wires 203 and 204, a problem arises in that a large parasitic capacitance is generated by the influence of the Miller effect, and this causes a delay and degradation of the electric power. It is therefore preferred that the adjacency length between wires such as a gate wire and a drain wire be set to be short.

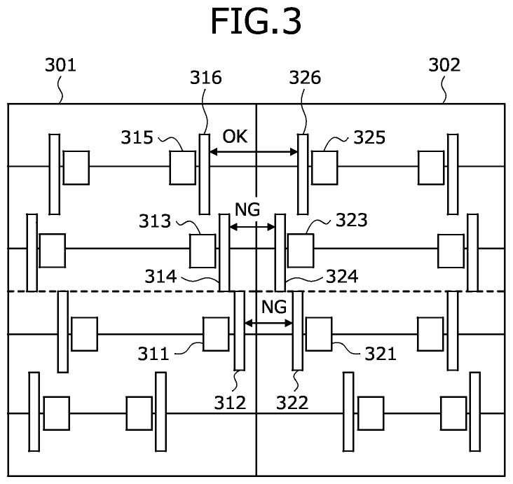

It may be considered that a branch wire may become unnecessary by disposing a cut metal at the foot of a via present at the side of the cell frame. When the cell is disposed, however, a distance by which no space error occurs between the cut metals on the same one wire cannot be secured and an error may occur. An example of the error occurring in a case where cut metals are disposed at the feet of vias is described with reference to FIG. 3.

FIG. 3 is an explanatory diagram depicting an example of the error occurring in the case where cut metals are disposed at the feet of vias. In FIG. 3, cells 301 and 302 are one example of two adjacent cells. In each of the cells 301 and 302, cut metals are disposed at the feet of vias present at the side of the cell frame.

In the cell 301, for example, a cut metal 312 is disposed at the foot of a via 311 present at the side of the cell frame. A cut metal 314 is disposed at the foot of a via 313 present at the side of the cell frame, and a cut metal 316 is disposed at the foot of a via 315 present at the side of the cell frame.

In the cell 302, for example, a cut metal 322 is disposed at the foot of a via 321 present at the side of the cell frame. A cut metal 324 is disposed at the foot of a via 323 present at the side of the cell frame, and a cut metal 326 is disposed at the foot of a via 325 present at the side of the cell frame.

A distance by which no space error occurs may be secured between the cut metal 316 and the cut metal 326 (OK). On the other hand, a distance by which no space error occurs cannot be secured between the cut metal 312 and the cut metal 322 (NG). Similarly, a distance by which no space error occurs cannot be secured between the cut metal 314 and the cut metal 324 (NG).

As described above, according to the disposal positions of the cut metals, a distance by which no space error occurs cannot be secured when the cells are disposed, resulting in an error occurs and thus, the cut metals cannot be disposed with no reason.

In the first embodiment, a design aiding method capable of suppressing the inter-wire capacitance caused by a wire not used in the wire connection (a branch wire) and suppressing an occurrence of a space error between the cut metals is described. An example of processes by the information processing device 101 (the processes (1) and (2) below) is described.

(1) The information processing device 101 disposes cells on a layout of a circuit under design, based on circuit information 110 related to the circuit under design. The circuit information 110 is, for example, a circuit diagram of the circuit under design. The layout is an area (a design diagram) to dispose cells thereon and execute wiring thereon.

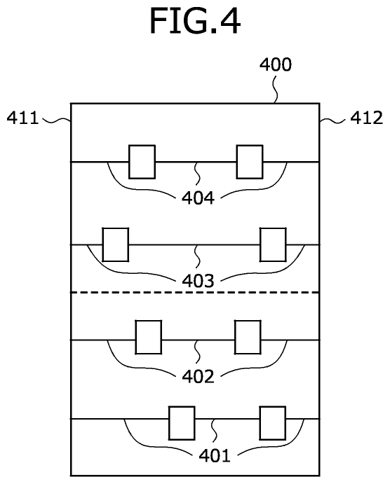

The cells to be disposed in the circuit under design are, for example, each a standard cell having no cut metal disposed on the cell frame thereof. The standard cell having no cut metal disposed on the cell frame thereof is described with reference to FIG. 4.

In the following description, the description is given taking four as an example of the number of the wires (extension wires) included in the standard cell. The number of the wires (the extension wires) included in the standard cell may be a number other than four.

FIG. 4 is an explanatory diagram depicting one example of the standard cell that has no cut metal disposed on the cell frame thereof. In FIG. 4, a cell 400 is one example of the standard cell that has no cut metal disposed on the cell frame thereof. The cell 400 includes wires (extension wires) 401 to 404. No cut metal is disposed on cell frames 411 and 412 of the cell 400.

The information processing device 101 disposes the standard cells that each have no cut metal disposed on the cell frame thereof like the cell 400 depicted in FIG. 4, in the layout of the circuit under design.

The cells 120 and 130 depicted in FIG. 1 are one example of the two cells adjacent to each other of the cells disposed in the layout of the circuit under design. Neither of the cells 120 and 130 has cut metal disposed on the cell frame thereof. The cells 120 and 130 therefore share therebetween branch wires of the cell and the adjacent cell as one long branch wire. For example, the cell 120 shares a branch wire 121 of the cell 120 and a branch wire 131 of the cell 130 as one long branch wire, with the cell 130.

(2) The information processing device 101 determines, for two adjacent cells of the cells disposed in the layout of the circuit under design, the disposal number and the disposal positions of the cut metals to be disposed between the two cells. For example, the information processing device 101 determines the disposal number and the disposal positions of the cut metals based on the length of each branch wire between a via on a wire in each cell and the cell frame of each cell of the two cells, and the type of wire that includes the branch wire.

In more detailed description, the information processing device 101 calculates, for the two cells, the length of the wire portion that is shared between the two cells based on the length of the branch wire of each of the cells. In a case where the calculated length is smaller than a specified value, the information processing device 101 determines the disposal number of the cut metal to be disposed in the shared wire portion to be “1”.

On the other hand, in a case where the calculated length is at least equal to the specified value, the information processing device 101 determines the disposal number of the cut metals to be disposed in the shared wire portion to be “2”. The specified value can be determined optionally. For example, a minimal distance between the cut metals by which no space error occurs is set as the specified value.

In the case where the disposal number of the cut metals is “2”, the information processing device 101 determines the disposal positions of the cut metals to be both ends of the shared wire portion. Both ends of the shared wire portion are, for example, the feet of the vias present at both ends of the shared wire portion. On the other hand, in the case where the disposal number of the cut metal is “1”, the information processing device 101 determines one position as the disposal position for the cut metal based on, for example, a degree of priority that depends on the type of the wire that includes the branch wires. The branch wires are the two branch wires forming the shared wire portion.

The type of the wire indicates any one of a gate wire, a drain wire, an internal wire, and a floating wire. As described above, the influence of the Miller effect is proportional to the adjacency length between a gate wire and a drain wire, increases the inter-wire capacitance, and causes a delay and electric power degradation. On the other hand, at a point adjacent to an internal wire or a floating wire, no influence of the Miller effect is present. In a case of a wire having a signal therein, an inter-wire capacitance other than that by the Miller effect is generated.

As described above, it can be stated that the degree of influence to the Miller effect by the branch wire differs according to the type of the wire. In the case where the disposal number of the cut metal is “1”, the information processing device 101 may therefore determine one point as the disposal position for the cut metal based on the degree of priority that depends on the type of the wire including the branch wires.

For example, the information processing device 101 compares the degrees of priority of the branch wires with each other. In a case where the degrees of priority of the branch wires differ from each other, the information processing device 101 determines the disposal position for the cut metal to be, for example, the foot of a via at the side of the branch wire having the higher degree of priority, of the shared wire portion. On the other hand, in a case where the degrees of priority of the branch wires are equal to each other, the information processing device 101 determines the disposal position for the cut metal to be, for example, a position on the cell frame in the shared wire portion.

In the example in FIG. 1, it is assumed, for example, that the length of a wire portion 140 (the branch wires 121 and 131) shared between the cells 120 and 130 is at least equal to the specified value. In this case, the information processing device 101 determines the disposal positions of the cut metals to be both ends of the shared wire portion 140. As a result, when cut metals 141 and 142 are disposed at both ends of the shared wire portion 140 (the feet of vias 161 and 162), the shared wire portion 140 (the branch wires) disappears and the signals between the cells 120 and 130 are separated from each other. Between the cut metals 141 and 142, a distance at least equal to the specified value is secured and no space error therefore occurs.

It is assumed that the length of a wire portion 150 shared between the cells 120 and 130 is smaller than the specified value. It is also assumed that the degrees of priority of the branch wires (the branch wire in the cell 120 and the branch wire in the cell 130) forming the shared wire portion 150 are equal to each other. In this case, the information processing device 101 determines the disposal position for the cut metal to be a position on a cell frame 170 of the shared wire portion 150. The cell frame 170 is a portion having therein the cell frame of the cell 120 and the cell frame of the cell 130 overlapping on each other. As a result, when a cut metal 151 is disposed on the cell frame 170 of the shared wire portion 150, the signals between the cells 120 and 130 are separated from each other.

As described above, according to the information processing device 101 of the first embodiment, in the layout design using the multi-patterning technique, efficient disposal positions of the cut metals capable of reducing the inter-wire capacitance (the parasitic capacitance) and suppressing occurrence of any space error between the cut metals can be determined.

In the example in FIG. 1, for the two cells 120 and 130 adjacent to each other, the cut metals are disposed at the disposal positions determined by the information processing device 101, the adjacency length between the gate wire and the drain wire can thereby be minimized, and the Miller effect can therefore be suppressed. In FIG. 1, a set of double-headed dotted arrows indicates the adjacency length between the gate wire and the drain wire.

The process of disposing the cut metals at the disposal positions determined by the information processing device 101 may be executed by, for example, the information processing device 101, or may be executed by another computer different from the information processing device 101.

An information processing device 101 according to a second embodiment is described next. In the following description, a case is described where the information processing device 101 according to the second embodiment is applied to a circuit designing device 501 in an information process system 500. The points similar to the points described in the first embodiment are not again depicted or described.

An example of a system configuration of the information process system 500 is be described first.

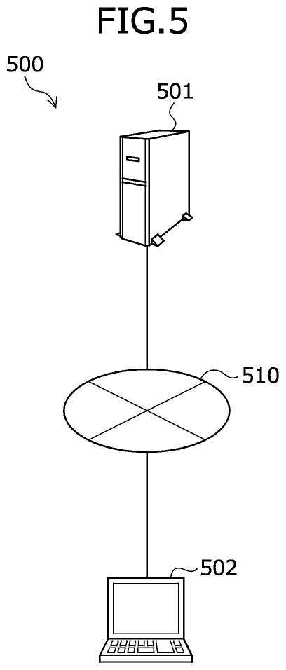

FIG. 5 is an explanatory diagram depicting an example of the system configuration of the information process system 500. In FIG. 5, the information process system 500 includes the circuit designing device 501 and a client device 502. In the information process system 500, the circuit designing device 501 and the client device 502 are connected to each other through a wired or a radio network 510. The network 510 is, for example, the Internet, a local area network (LAN), or a wide area network (WAN).

The circuit designing device 501 is, for example, a server. The client device 502 is a computer used by a user of the information process system 500. The user is, for example, a designer of a semiconductor integrated circuit. The client device 502 is, for example, a personal computer (PC) or a tablet PC.

While the devices are not limited to the above, it is assumed that the circuit designing device 501 and the client device 502 are disposed each being different from each other. For example, the circuit designing device 501 may be realized by the client device 502. The information process system 500 may include plural client devices 502.

Next, an example of a hardware configuration of the circuit designing device 501 is described.

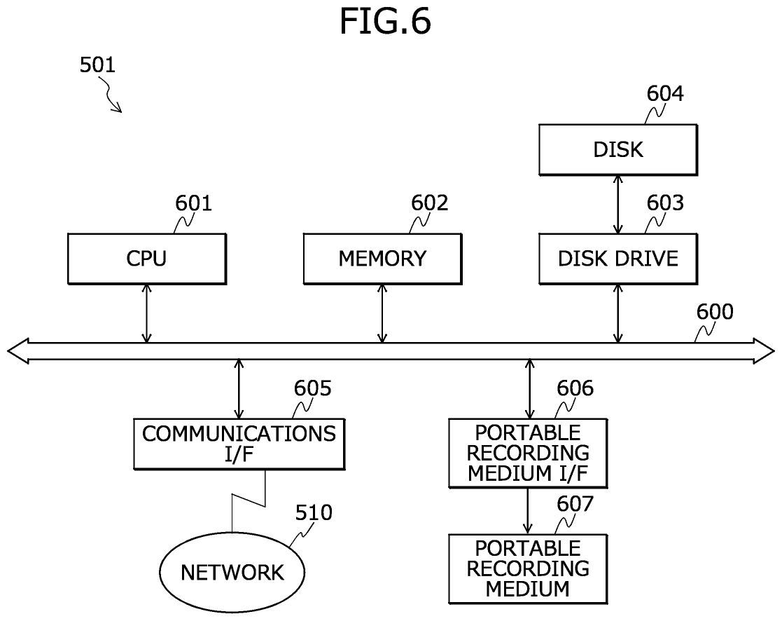

FIG. 6 is a block diagram depicting an example of a hardware configuration of the circuit designing device 501. In FIG. 6, the circuit designing device 501 has a CPU 601, a memory 602, a disk drive 603, a disk 604, a communications interface (I/F) 605, a portable recording medium I/F 606, and a portable recording medium 607. Further, components are connected to one another by a bus 600.

Here, the CPU 601 governs overall control of the circuit designing device 501. The CPU 601 may have multiple cores. The memory 602, for example, includes a read-only memory (ROM), a random access memory (RAM), and a flash ROM. In particular, for example, the flash ROM stores OS programs, the ROM stores application programs, and the RAM is used as a work area of the CPU 601. Programs stored in the memory 602 are loaded onto the CPU 601, whereby encoded processes are executed by the CPU 601.

The disk drive 603, under the control of the CPU 601, controls the reading and writing of data with respect to the disk 604. The disk 604 stores therein data written thereto under the control of the disk drive 603. The disk 604 may be, for example, a magnetic disk, an optical disk, etc.

The communications I/F 605 is connected to the network 510 through a communications line and is connected to an external computer (for example, the client device 502 depicted in FIG. 5) through the network 510. Further, the communications I/F 605 administers an internal interface with the network 510 and controls the input and output of data from an external computer. As the communications I/F 605, for example, a modem, a LAN adapter, etc. may be employed.

The portable recording medium I/F 606, under the control of the CPU 601, controls the reading and writing of data with respect to the portable recording medium 607. The portable recording medium 607 store data written thereto under the control of the portable recording medium I/F 606. The portable recording medium 607 may be, for example, a compact disk (CD)-ROM, a Digital Versatile Disk (DVD), universal serial bus (USB) memory, etc.

The circuit designing device 501 may include, for example, an input device and a display in addition to the above components. The client device 502 depicted in FIG. 5 may also be realized by a hardware configuration similar to that of the circuit designing device 501. The client device 502 however includes, for example, an input device and a display in addition to the above components.

An example of the functional configuration of the circuit designing device 501 is described next.

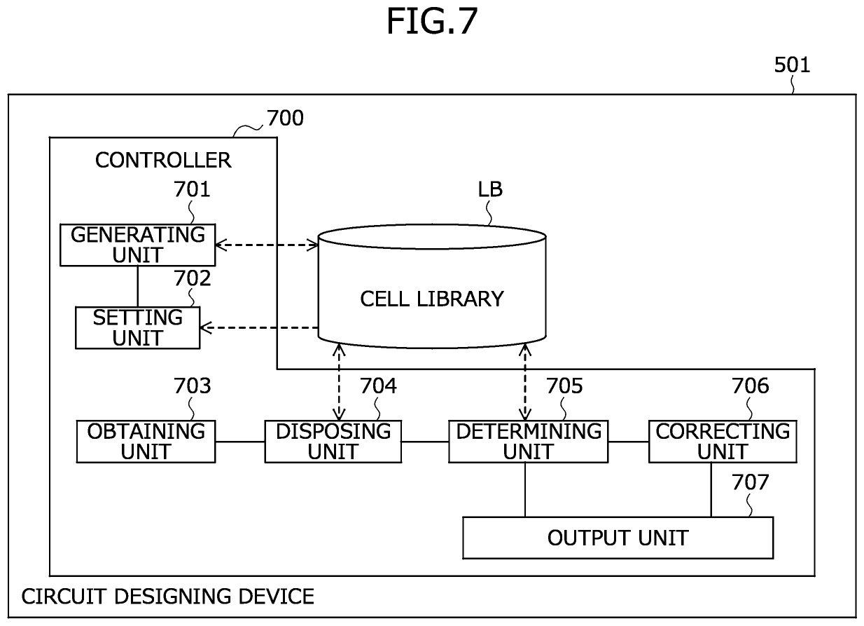

FIG. 7 is a block diagram depicting an example of a functional configuration of the circuit designing device 501. In FIG. 7, the circuit designing device 501 includes a generating unit 701, a setting unit 702, an obtaining unit 703, a disposing unit 704, a determining unit 705, a correcting unit 706, an output unit 707, and a cell library LB. The generating unit 701 to the output unit 707 are functions constituting a controller 700 and are realized, for example, by causing the CPU 601 to execute programs stored in a storage device such as, for example, the memory 602, the disk 604, or the portable recording medium 607 or by the communications I/F 605 depicted in FIG. 6. The processing results of each of the functional units are stored to a storage device such as, for example, the memory 602 or the disk 604. The cell library LB is realized by a storage device such as, for example, the memory 602 or the disk 604. The cell library LB may be retained by another computer accessible from the circuit designing device 501.

The generating unit 701 generates a standard cell SC. The standard cell SC is a standard cell that has no cut metal disposed on the cell frame thereof. The standard cell SC is described by, for example, a circuit diagram or layout data. For example, the generating unit 701 generates the standard cell SC based on, for example, an operational input by a user (a designer) using an input device not depicted.

The generated standard cell SC is stored in, for example, the cell library LB.

The setting unit 702 sets positioning information for the generated standard cell SC. The positioning information is the information used to determine the disposal number and the disposal positions of the cut metals. The positioning information includes, for example, the length of each of the branch wires in the standard cell SC as the information to determine the disposal number of the cut metals. The branch wires are each a wire between a via and a cell frame.

The positioning information includes, for example, the degree of priority of each of the branch wires in the standard cell SC as the information to determine the disposal positions of the cut metals. The degree of priority of a branch wire is set according to the type of the wire that includes the branch wire in the standard cell SC taking into consideration, for example, the degree of influence to the Miller effect.

For example, the setting unit 702 obtains the length of each of the branch wires in the standard cell SC by referring to, for example, the circuit diagram or the layout data of the standard cell SC. The setting unit 702 sets, for each of the branch wires in the standard cell SC, the degree of priority according to the type of the wire including the branch wire. The type of the wire indicates any one of a gate wire, a drain wire, an internal wire, and a floating wire. The type of the wire is identified from, for example, the circuit diagram or the layout data of the standard cell SC.

In the following description, the branch wire for which the degree of priority is to be set may be denoted as “object branch wire” for convenience. A pair of adjacent wires in the standard cell SC may be denoted as “pair-wires”.

In more detailed description, for example, the setting unit 702 determines whether pair-wires of a wire that includes the object branch wire and another wire adjacent to the wire in the standard cell SC are pair-wires of a gate wire and a drain wire. In a case where the setting unit 702 determines that the pair-wires are the pair-wires of a gate wire and a drain wire, the setting unit 702 sets, for the object branch wire, a degree of priority that is higher than that of the branch wire of each of the other pairs.

In a case where the pair-wires are the pair-wires of a gate wire and a drain wire, the setting unit 702 may further set a degree of priority for the object branch wire according to the result of a comparison between the length of the object branch wire and the length of the other branch wire included in the other wire of the same pair-wires. The other branch wire is the branch wire adjacent to the object branch wire.

For example, in a case where the length of the object branch wire is greater than the length of the other branch wire, the setting unit 702 may set a degree of priority that is higher than that of the other branch wire, for the object branch wire. On the other hand, in a case where the length of the object branch wire is smaller than the length of the other branch wire, the setting unit 702 may set a degree of priority that is lower than that of the other branch wire, for the object branch wire. In a case where the length of the object branch wire is equal to the length of the other branch wire, the setting unit 702 may set a degree of priority that is equal to that of the other branch wire, for the object branch wire.

It is assumed that the pair-wires including the object branch wire are pair-wires of a floating wire and a wire other than a floating wire. The wire other than a floating wire is any one signal wire of a drain wire, a gate wire, and an internal wire.

At this time, in a case where the wire including the object branch wire is a wire other than a floating wire, the setting unit 702 may set, for the object branch wire, a degree of priority that is higher than that of another branch wire included in another wire. The setting unit 702 sets, for the standard cell SC, the positioning information including the obtained length of the branch wire and the set degree of priority of the branch wire.

A case may be present where two other wires are present adjacent to the wire that includes the object branch wire. For example, in a case where the other two wires are present adjacently above and below the wire that includes the object branch wire, two sets of pair-wires each including the object branch wire are formed. When the degree of priority of the object branch wire is determined for each of the two sets of pair-wires, different degrees of priority may be set. In this case, the setting unit 702 may set, for example, the degree of priority that is the higher one of the different degrees of priority, for the object branch wire.

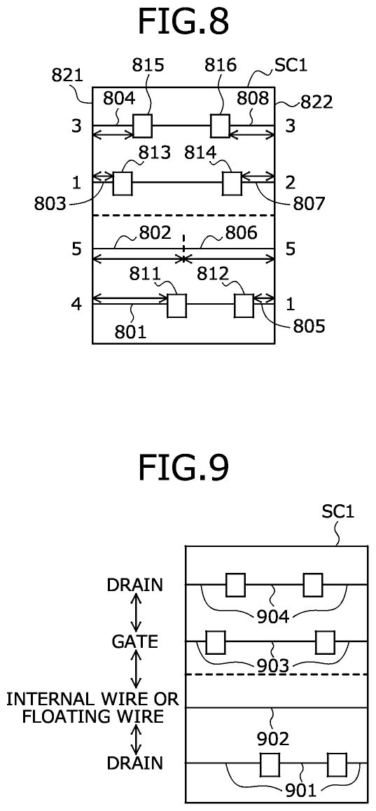

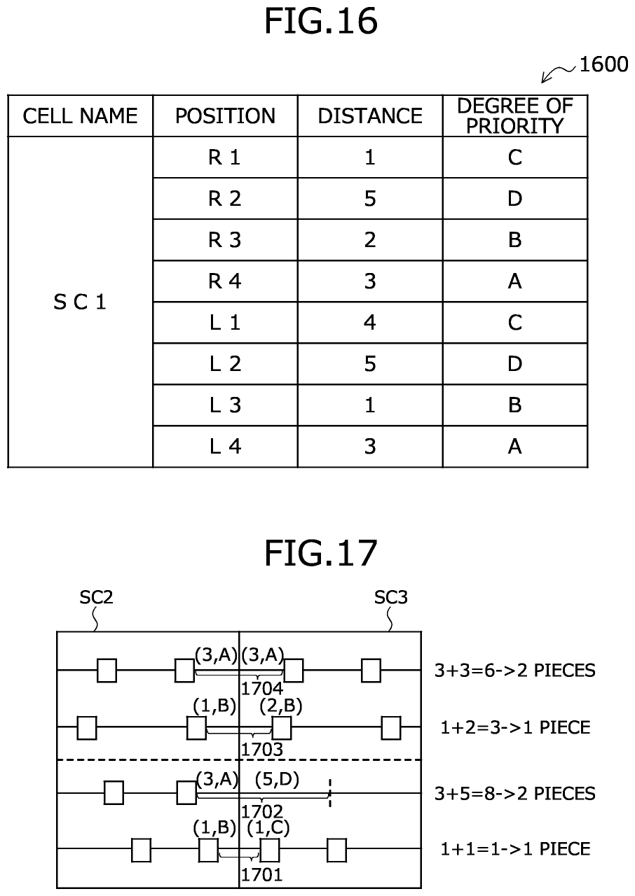

The set positioning information is correlated with the standard cell SC and stored to, for example, the cell library LB. An example of obtaining the length of the branch wire is described later with reference to FIG. 8. An example of the setting of the degree of priority for the branch wire is described later with reference to FIG. 9 to FIG. 14. An example of the setting of the positioning information is described later with reference to FIG. 15 to FIG. 16.

In the following description, the standard cell SC may simply be denoted by “cell SC”.

The obtaining unit 703 obtains the circuit information related to the circuit under design. The circuit information is, for example, a circuit diagram related to the circuit under design. The circuit diagram is information concerning, for example, the parts of the circuit under design and links indicating their connection. For example, the obtaining unit 703 obtains the circuit information by receiving the circuit information from, for example, the client device 502 depicted in FIG. 5. The obtaining unit 703 may obtain the circuit information based on an operational input by a user using an input device not depicted.

The disposing unit 704 disposes the standard cells SC in the layout of the circuit under design, based on the circuit information related to the circuit under design. For example, the disposing unit 704 disposes the generated cells SC in the layout of the circuit under design by referring to the cell library LB based on the circuit diagram related to the circuit under design.

The determining unit 705 determines, for two adjacent cells SC of the cells SC disposed in the layout of the circuit under design, the disposal number and the disposal positions of the cut metals to be disposed between the two cells SC, based on the length of a branch wire and the type of the wire that includes the branch wire. The branch wire is a wire between a via on a wire in each cell SC of the two cells SC and a cell frame of each cell SC thereof.

For example, the determining unit 705 calculates, for two cells SC, the length of the wire portion shared between the two cells SC based on the length of the branch wire. The determining unit 705 may determine the disposal number and the disposal positions of the cut metals to be disposed on the shared wire portion based on the calculated length of the shared wire portion and the type of the wire.

For example, the determining unit 705 may determine the disposal number and the disposal positions of the cut metals to be disposed on the shared wire portion based on the calculated length of the shared wire portion and the degree of priority set for each of the branch wires that form the shared wire portion.

The degree of priority set for each branch wire is the degree of priority set according to, for example, the type of the wire including each branch wire (a gate wire, a drain wire, an internal wire, or a floating wire). The degree of priority set for each branch wire may be the degree of priority set according to, for example, the result of a comparison between the length of each branch wire and the length of another branch wire included in another wire of the same pair-wires.

In more detailed description, for example, the determining unit 705 obtains the positioning information of each of the two adjacent cells SC from the cell library LB. The determining unit 705 next calculates, for the two cells SC, the length of the wire portion shared between the two cells SC based on the length of the branch wire identified from the obtained positioning information.

The determining unit 705 determines whether the calculated length of the shared wire portion is at least equal to a specified value. The specified value is set to be, for example, the minimal distance between the cut metals, that causes no space error to occur. In a case where the determining unit 705 determines that the calculated length is smaller than the specified value, the determining unit 705 determines the disposal number of the cut metal to be disposed on the shared wire portion to be “1”.

The determining unit 705 determines one point as the disposal position for the cut metal. For example, the determining unit 705 compares the degrees of priority of the branch wires that form the shared wire portion with each other by referring to the obtained positioning information. In a case where the degrees of priority of the branch wires are different from each other, the determining unit 705 may determine the foot of a via on the side of the branch wire whose degree of priority is the higher one of the shared wire portion as the disposal position for the cut metal. On the other hand, in a case where the degrees of priority of the branch wires are equal to each other, the determining unit 705 may determine a position on the cell frame in the shared wire portion as the disposal position for the cut metal.

In a case where the calculated length of the shared wire portion is at least equal to the specified value, the determining unit 705 determines the disposal number of the cut metals to be disposed on the shared wire portion to be “2”. The determining unit 705 may determine the disposal positions of the cut metals to be both ends of the shared wire portion.

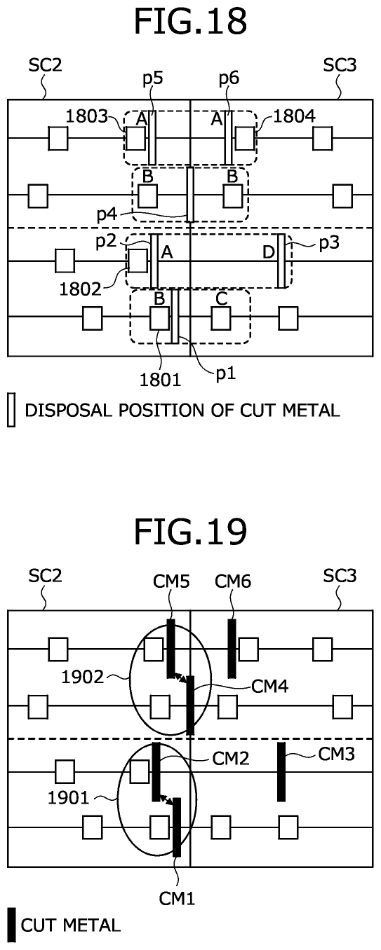

The determining unit 705 disposes the cut metals of the determined disposal number at the determined disposal positions. An example of the determination of the disposal number and the disposal positions of the cut metals is described later with reference to FIG. 17 and FIG. 18.

The correcting unit 706 corrects the disposal positions of the disposed cut metals. For example, the correcting unit 706 determines whether any space error occurs as the result of the cut metals of the determined disposal number being disposed at the determined disposal positions. The presence or the absence of the space error is determined by executing, for example, a design rule check.

The design rule check is a process to verify whether a violation of the design rules (the rules for the designing) is present. The space error occurs by, for example, the positional relation between one cut metal and another cut metal disposed in the vertical direction of the one cut metal. Here, the space between the cut metals may be already secured in the lateral direction of the two adjacent cells SC (the wire direction).

In the vertical direction of the two adjacent cells SC, however, the space error may occur. In a case where a space error occurs, the correcting unit 706 corrects the disposal position for at least any one of the cut metals at the point at which the space error occurs, to a position on the cell frame in a border portion of the two adjacent cells.

In more detailed description, it is assumed, for example, that any one of the two cut metals with which a space error occurs is present on a cell frame (Case 1). In this case, the correcting unit 706 moves the cut metal not present on the cell frame of the two cut metals, to a position on the cell frame. It is assumed that none of the two cut metals is present on the cell frame (Case 2). In this case, the correcting unit 706 moves the cut metal that is closer to the cell frame of the two cut metals, to a position on the cell frame. In a case where a new error occurs due to the move of the cut metal, the correcting unit 706 may execute the correction in Case 1.

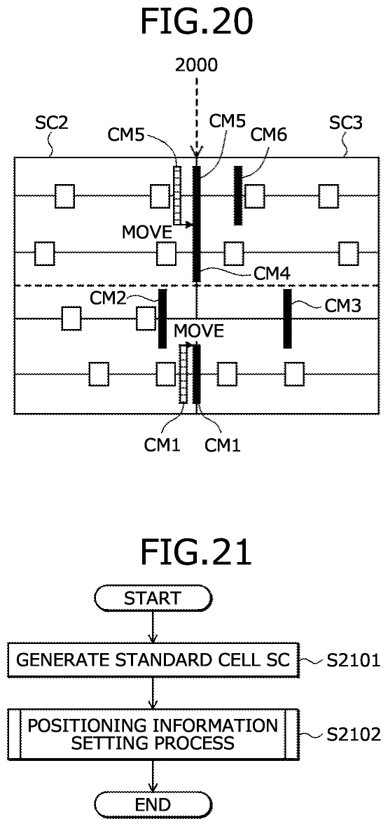

An example of occurrence of a space error between cut metals is described later with reference to FIG. 19. An example of the correction of the disposal position for a cut metal is described later with reference to FIG. 20.

The output unit 707 outputs layout data related to the circuit under design that has the cut metals of the determined disposal number disposed at the determined disposal positions. In a case where the disposal position for the cut metal is corrected, the output unit 707 outputs the layout data after the correction. The layout data is, for example, a layout for which a wiring process for the cells SC is executed. The layout data may be layout data for which layout correction is executed by executing layout vs. schematic (LVS)/design rule check (DRC).

Forms of the output of the output unit 707 include, for example, storage to a storage device such as the memory 602 or the disk 604, transmission to another computer by the communications I/F 605, display on a display not depicted, and output to a printer (not depicted) for printing. For example, the output unit 707 may transmit the layout data related to the circuit under design, to the client device 502.

The output unit 707 may output the design information with which the determined disposal number and the determined disposal positions of the cut metals may be identified, for the circuit under design having therein the cells SC disposed in the layout. For example, another computer may thereby dispose and connect the cut metals of the determined disposal number at the determined disposal positions, by referring to the design information.

The functional units of the circuit designing device 501 may be realized by plural computers (such as, for example, the circuit designing device 501 and the client device 502) in the information process system 500. For example, the generating unit 701 and the setting unit 702 may be realized by the client device 502, and the obtaining unit 703, the disposing unit 704, the determining unit 705, the correcting unit 706, and the output unit 707 may be realized by the circuit designing device 501.

An example of obtaining the length of the branch wire is described next with reference to FIG. 8.

FIG. 8 is an explanatory diagram depicting an example of obtaining the length of the branch wire. In FIG. 8, a cell SC1 is one example of the standard cell SC. The cell SC1 includes branch wires 801 to 808. The branch wire 801 is a wire between a via 811 and a cell frame 821. In the case of a floating wire, no via is disposed on the wire. In this case, it is assumed that sections formed by dividing a portion between the cell frame 821 and a cell frame 822 at a central point thereof are each handled as a branch wire. The branch wire 802 is the wire that is the left-side one of the sections formed by dividing the portion between the cell frames 821 and 822 at the central point thereof.

The branch wire 803 is a wire between a via 813 and the cell frame 821. The branch wire 804 is a wire between a via 815 and the cell frame 821. The branch wire 805 is a wire between a via 812 and the cell frame 822. The branch wire 806 is a wire that is the right-side one of the sections formed by dividing the portion between the cell frames 821 and 822 at the central point thereof. The branch wire 807 is a wire between a via 814 and the cell frame 822. The branch wire 808 is a wire between a via 816 and the cell frame 822.

The setting unit 702 obtains the lengths of the branch wires 801 to 808 in the cell SC1. In the example in FIG. 8, the length of the branch wire 801 is “4”. The length of the branch wire 802 is “5”. The length of the branch wire 803 is “1”. The length of the branch wire 804 is “3”. The length of the branch wire 805 is “1”. The length of the branch wire 806 is “5”. The length of the branch wire 807 is “2”. The length of the branch wire 808 is “3”.

An example of the setting of the degree of priority of the branch wire is described next with reference to FIG. 9 to FIG. 14.

FIGS. 9, 10, 11, 12, 13, and 14 are explanatory diagrams depicting an example of the setting of the degree of priority of the branch wire. In FIG. 9, the cell SC1 includes wires 901, 902, 903, and 904. It is assumed that the wire 901 is a drain wire and the wire 902 is an internal wire or a floating wire. It is assumed that the wire 903 is a gate wire and the wire 904 is a drain wire.

The setting unit 702 determines whether the pair-wires 901 and 902 are pair-wires of a gate wire and a drain wire. The pair-wires 901 and 902 are not pair-wires of a gate wire and a drain wire. In this case, the setting unit 702 sets a degree of priority as “low” for each of the branch wires (the branch wires 801, 802, 805, and 806 depicted in FIG. 8) of the pair-wires 901 and 902. While described in detail later, the degree of priority of “low” is classified into a degree of priority of “C” and a degree of priority of “D”.

The setting unit 702 determines whether the pair-wires 902 and 903 are pair-wires of a gate wire and a drain wire. The pair-wires 902 and 903 are not pair-wires of a gate wire and a drain wire. In this case, for each of the branch wires (the branch wires 802, 803, 806, and 807 depicted in FIG. 8) of the pair-wires 902 and 903, the setting unit 702 sets the degree of priority as “low”. While described in detail later, the degree of priority of “low” is classified into the degree of priority of “C” and the degree of priority of “D”.

The branch wires 802 and 806 are included in the pair-wires 901 and 902, and the pair-wires 902 and 903. For each of the branch wires 802 and 806, the degree of priority is therefore redundantly set. In this case, the setting unit 702 sets, for example, the degree of priority that is the higher one of the degrees of priority set for the branch wires 802 and 806, for each of the branch wires 802 and 806. For each of the pair-wires 901 and 902, and the pair-wires 902 and 903, the degree of priority of “low” is set for each of the branch wires 802 and 806. In this case, the setting unit 702 sets the degree of priority for each of the branch wires 802 and 806 as “low”.

The setting unit 702 determines whether the pair-wires 903 and 904 are pair-wires of a gate wire and a drain wire. The pair-wires 903 and 904 are pair-wires of a gate wire and a drain wire. In this case, the setting unit 702 sets the degree of priority as “high” for each of the branch wires (the branch wires 803, 804, 807, and 808 depicted in FIG. 8) of the pair-wires 903 and 904. While the details are described later, the degree of priority of “high” is classified into a degree of priority of “A” and a degree of priority of “B”.

The branch wires 803 and 807 are included in the pair-wires 902 and 903, and the pair-wires 903 and 904. For each of the branch wires 803 and 807, the degree of priority is therefore redundantly set. In this case, the setting unit 702 sets, for example, the degree of priority that is the higher one of the degrees of priority set for the branch wires 803 and 807, for each of the branch wires 803 and 807. For the pair-wires 902 and 903, the degree of priority of “low” is set for each of the branch wires 803 and 807. On the other hand, for the pair-wires 903 and 904, the degree of priority of “high” is set for each of the branch wires 803 and 807. In this case, the setting unit 702 sets the degree of priority for each of the branch wires 803 and 807 as “high”.

The setting unit 702 may thereby set the degree of priority that is high, for the branch wires of the pair-wires greatly affected by the Miller effect.

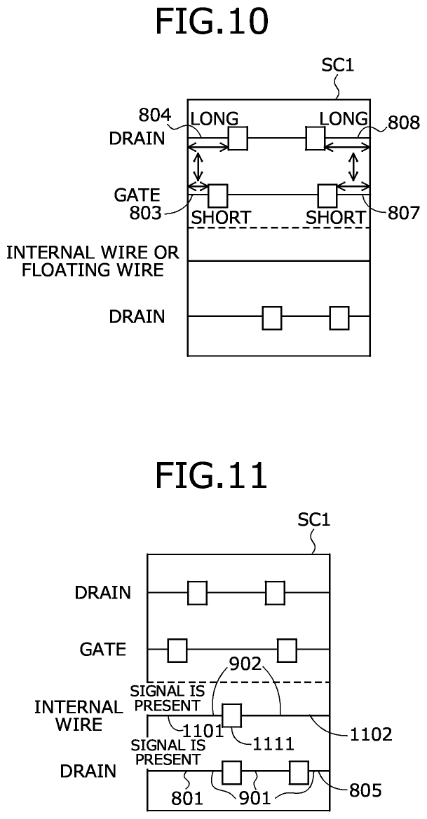

In FIG. 10, the setting unit 702 compares the lengths of the adjacent branch wires with each other for the pair-wires 903 and 904, which are a gate wire and a drain wire (see FIG. 9). In the example in FIG. 10, the setting unit 702 compares the length of the branch wire 803 and the length of the branch wire 804 with each other. The length of the branch wire 804 is longer than the length of the branch wire 803. In this case, to minimize the adjacency length between the pair-wires 903 and 904, the setting unit 702 sets the degree of priority for the branch wire 804, which is the longer one, as “A”, thereby making the degree of priority higher than that of the branch wire 803. The setting unit 702 sets the degree of priority for the branch wire 803, which is the shorter one, as “B”, thereby making the degree of priority lower than that of the branch wire 804.

The setting unit 702 compares the length of the branch wire 807 and the length of the branch wire 808 with each other. The length of the branch wire 808 is longer than the length of the branch wire 807. In this case, the setting unit 702 sets the degree of priority for the branch wire 808 as “A”, which is higher than that of the branch wire 807, which is the longer one. The setting unit 702 sets the degree of priority for the branch wire 807 as “B”, which is lower than that of the branch wire 808, which is the shorter one.

In FIG. 11, it is assumed that the wire 902 in the cell SC1 is an internal wire and a via 1111 is disposed on the wire 902. A branch wire 1101 is a wire between the via 1111 and the cell frame 821 (see FIG. 8). A branch wire 1102 is a wire between the via 1111 and the cell frame 822 (see FIG. 8). In this case, the wires 901 and 902 are free of any influence of the Miller effect while the wires 901 and 902 each have a signal present therein and an inter-wire capacitance other than that by the Miller effect is therefore generated.

For the pair-wires 901 and 902, which are a drain wire and an internal wire, the setting unit 702 therefore sets the degree of priority for each of the branch wires 801, 805, 1101, and 1102 as “C”. The degree of priority of “C” is a degree of priority that is lower than the degrees of priority of “A” and “B” and that is higher than the degree of priority of “D” described later.

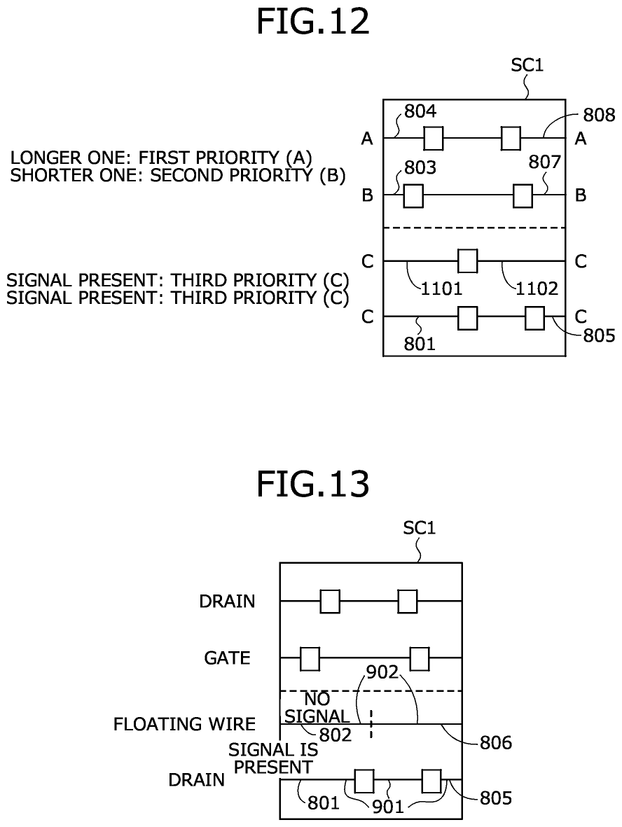

In the example in FIG. 12, the degrees of priority that are set for the branch wires 801, 803, 804, 805, 807, 808, 1101, and 1102 in the cell SC1 are shown.

In FIG. 13, it is assumed that the wire 902 in the cell SC1 is a floating wire. In this case, the wire 901 is free of any influence of the Miller effect while the wire 901 has a signal therein and an inter-wire capacitance other than that by the Miller effect is therefore generated. Almost no inter-wire capacitance is generated for the wire 902.

Thus, with respect to the pair-wires 901 and 902, which are a drain wire and a floating wire, the setting unit 702 sets the degree of priority for the branch wires 801 and 805 as “C”. The setting unit 702 sets the degree of priority for each of the branch wires 802 and 806 as “D”.

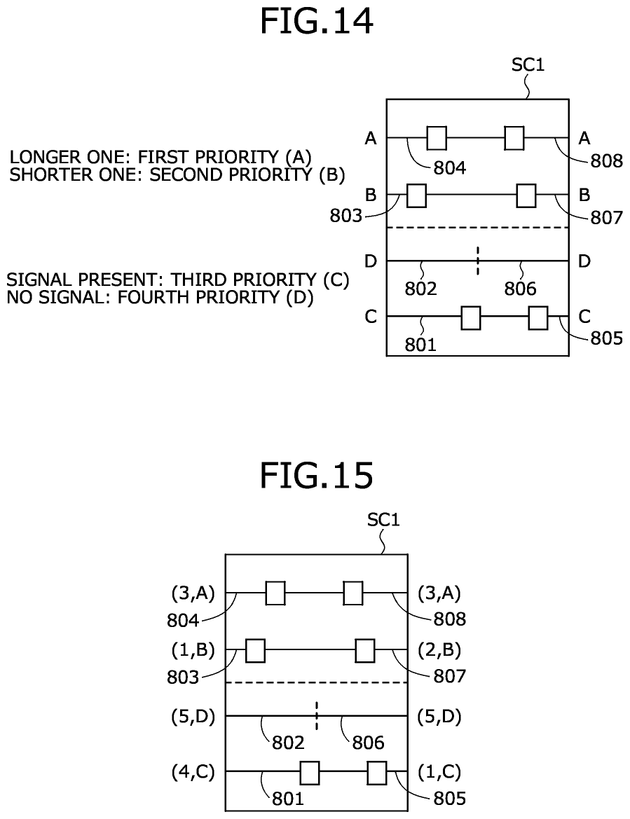

In the example in FIG. 14, the degrees of priority set for the branch wires 801 to 808 in the cell SC1 are shown.

An example of the setting of the positioning information is described next with reference to FIG. 15 and FIG. 16.

FIG. 15 is an explanatory diagram depicting an example of the setting of the positioning information. In FIG. 15, (the length of the branch wire, the degree of priority) are set for each of the branch wires 801 to 808 in the cell SC1. For example, (4, C) are set for the branch wire 801. “(4, C)” indicates that the length of the branch wire 801 is “4” and the degree of priority thereof is “C”.

An example of the data structure of the positioning information stored in the cell library LB is described with reference to FIG. 16.

FIG. 16 is an explanatory diagram depicting an example of the data structure of the positioning information. In FIG. 16, positioning information 1600 includes items of “cell name”, “position”, “distance”, and “degree of priority”, and information concerning each branch wire is stored as a record by setting information for each of the items.

The “cell name” is an identifier that uniquely identifies the cell SC. The “position” represents the position of a branch wire in the cell SC. “UR” indicates whether a branch wire is on the right side or the left side. Numbers “1 to 4” each indicates how many branch wires are present under the branch wire including the branch wire. For example, “L4” indicates the position of the branch wire 804 (see FIG. 15) that is the fourth one from the bottom on the left side in the cell SC1. The “distance” is the distance from a via to a cell frame and represents the length of the branch wire. The “degree of priority” represents the degree of priority of the branch wire.

An example of the determination of the disposal number and the disposal positions of cut metals is described next with reference to FIG. 17 and FIG. 18.

FIG. 17 is an explanatory diagram depicting an example of the determination of the disposal number of cut metal. In FIG. 17, cells SC2 and SC3 are one example of two adjacent cells. The determining unit 705 obtains the positioning information of each of the cells SC2 and SC3 from the cell library LB. The determining unit 705 next calculates the lengths of wire portions 1701 to 1704 that are shared between the cells SC2 and SC3, based on the lengths of branch wires identified from the obtained positioning information, for the cells SC2 and SC3. The shared wire portions 1701 to 1704 may be simply denoted below as “wire portions 1701 to 1704”.

The wire portion 1701 includes a branch wire at a position R1 in the cell SC2 and a branch wire at a position L1 in the cell SC3. In this case, the determining unit 705 calculates the length of “2” of the wire portion 1701 by adding the length of “1” of the branch wire at the position R1 in the cell SC2 and the length of “1” of the branch wire at the position L1 in the cell SC3.

The determining unit 705 determines whether the calculated length of “2” of the wire portion 1701 is at least equal to a specified value. It is assumed that the specified value is “4”. In this case, the length of “2” of the wire portion 1701 is smaller than the specified value and the determining unit 705 therefore determines the disposal number of the cut metal to be disposed on the wire portion 1701 to be “1”.

The wire portion 1702 includes a branch wire at a position R2 in the cell SC2 and a branch wire at a position L2 in the cell SC3. In this case, the determining unit 705 calculates the length of “8” of the wire portion 1702 by adding the length of “3” of the branch wire at the position R2 in the cell SC2 and the length of “5” of the branch wire at the position L2 in the cell SC3. The determining unit 705 determines whether the calculated length of “8” of the wire portion 1702 is at least equal to the specified value. The length of “8” of the wire portion 1702 is at least equal to the specified value and the determining unit 705 therefore determines the disposal number of the cut metals to be disposed on the wire portion 1702 to be “2”.

The wire portion 1703 includes a branch wire at a position R3 in the cell SC2 and a branch wire at a position L3 in the cell SC3. In this case, the determining unit 705 calculates the length of “3” of the wire portion 1703 by adding the length of “1” of the branch wire at the position R3 in the cell SC2 and the length of “2” of the branch wire at the position L3 in the cell SC3.

The determining unit 705 determines whether the calculated length of “3” of the wire portion 1703 is at least equal to the specified value. The length of “3” of the wire portion 1703 is smaller than the specified value and the determining unit 705 therefore determines the disposal number of the cut metal to be disposed on the wire portion 1703 to be “1”.

The wire portion 1704 includes a branch wire at a position R4 in the cell SC2 and a branch wire at a position L4 in the cell SC3. In this case, the determining unit 705 calculates the length of “6” of the wire portion 1704 by adding the length of “3” of the branch wire at the position R4 in the cell SC2 and the length of “3” of the branch wire at the position L4 in the cell SC3.

The determining unit 705 determines whether the calculated length of “6” of the wire portion 1704 is at least equal to the specified value. The length of “6” of the wire portion 1704 is at least equal to the specified value and the determining unit 705 therefore determines the disposal number of the cut metals to be disposed on the wire portion 1704 to be “2”.

An example of the determination of the disposal positions of the cut metals is described next with reference to FIG. 18.

FIG. 18 is an explanatory diagram depicting an example of the determination of the disposal positions of the cut metals. In FIG. 18, the determining unit 705 determines the disposal positions of the cut metals for the wire portions 1701 to 1704 that are shared between the cells SC2 and SC3.

The disposal number of the cut metal to be disposed on the wire portion 1701 is “1”. In this case, the determining unit 705 identifies the degree of priority of “B” of the branch wire at the position R1 in the cell SC2 and the degree of priority of “C” of the branch wire at the position L1 in the cell SC3 that form the wire portion 1701, by referring to the obtained positioning information.

The determining unit 705 next compares the degree of priority of “B” of the branch wire at the position R1 in the cell SC2 and the degree of priority of “C” of the branch wire at the position L1 in the cell SC3 with each other. The branch wire at the position R1 in the cell SC2 has a degree of priority that is higher than that of the branch wire at the position L1 in the cell SC3. In this case, the determining unit 705 determines the disposal position for the cut metal to be the foot of a via 1801 on the side of the branch wire at the position R1 in the cell SC2 (corresponding to a position p1 in FIG. 18).

The disposal number of the cut metals to be disposed on the wire portion 1702 is “2”. In this case, the determining unit 705 determines the disposal positions of the cut metals to be both ends of the wire portion 1702 (corresponding to positions p2 and p3 in FIG. 18). The position p2 is the foot of a via 1802 on the side of the branch wire at the position R2 in the cell SC2. The second wire from the bottom in the cell SC3 is a floating wire and therefore includes no via. The position p3 therefore corresponds to the central portion of the second wire from the bottom in the cell SC3. The position p3 may, however, be present on the left side of the central portion when the position p3 is distant from the position p2 by a distance longer than specified.

The disposal number of the cut metal to be disposed on the wire portion 1703 is “1”. In this case, the determining unit 705 identifies the degree of priority of “B” of the branch wire at the position R3 in the cell SC2 and the degree of priority of “B” of the branch wire at the position L3 in the cell SC3 that form the wire portion 1703 by referring to the obtained positioning information.

The determining unit 705 next compares the degree of priority of “B” of the branch wire at the position R3 in the cell SC2 and the degree of priority of “B” of the branch wire at the position L3 in the cell SC3 with each other. These degrees of priority are equal to each other. In this case, the determining unit 705 determines the disposal position for the cut metal to be “p4” on the cell frame of the wire portion 1703.

The disposal number of the cut metals to be disposed on the wire portion 1704 is “2”. In this case, the determining unit 705 determines the disposal positions of the cut metals to be both ends of the wire portion 1704 (corresponding to positions p5 and p6 in FIG. 18). The position p5 is the foot of a via 1803 on the side of the branch wire at the position R4 in the cell SC2. The position p6 is the foot of a via 1804 on the side of the branch wire at the position L4 in the cell SC3.

As described above, in the case where the disposal number is “1”, the circuit designing device 501 may enhance the effect of reducing the inter-wire capacitance and prevent space error, by disposing the cut metal at the foot of the via having the higher degree of priority. In a case where the disposal number is “2”, the circuit designing device 501 may enhance the effect of reducing the inter-wire capacitance and prevent space error, by disposing the cut metals at the feet of both of the vias.

An example of correction of the disposal position for the cut metal is described next. An example of occurrence of a space error between the cut metals is first described with reference to FIG. 19.

FIG. 19 is an explanatory diagram depicting an example of occurrence of a space error between the cut metals. In FIG. 19, for the adjacent cells SC2 and SC3, the state is depicted of a case where cut metals CM1 to CM6 are disposed at the positions p1 to p6 for the arrangement depicted in FIG. 18 and, as a result, a space error occurs between the cut metals.

While space between the cut metals may be secured for the lateral direction (the wire direction) of the adjacent cells SC2 and SC3, a space error may occur in the vertical direction thereof. In FIG. 19, reference numerals 1901 and 1902 each denote an error location.

The error location 1901 indicates a space error that occurs because the distance in the vertical direction between the cut metal CM1 and the cut metal CM2 is smaller than the specified value. The error location 1902 indicates a space error that occurs because the distance in the vertical direction between the cut metal CM4 and the cut metal CM5 is smaller than the specified value. In this case, the correcting unit 706 corrects the disposal positions of the disposed cut metals.

FIG. 20 is an explanatory diagram depicting an example of the correction of the disposal positions of the cut metals. In FIG. 20, for the error location 1901 depicted in FIG. 19, the correcting unit 706 corrects the disposal position for the cut metal CM1 by moving the cut metal CM1 to a position on a cell frame 2000 in the border portion between the cells CM2 and CM3. The correcting unit 706 may thereby secure the distance in the vertical direction between the cut metal CM1 and the cut metal CM2.

For the error location 1902 depicted in FIG. 19, the correcting unit 706 corrects the disposal position for the cut metal CM5 by moving the cut metal CM5 to a position on the cell frame 2000 in the border portion between the cells CM2 and CM3. As the result of correcting the disposal position for the cut metal CM5, the cut metal CM4 and the cut metal CM5 overlap each other on the cell frame 2000 and thereby form one cut metal, and occurrence of a space error may therefore be suppressed.

A space error may occur between the cut metal CM5 and the cut metal CM6 as the result of correcting the disposal position for the cut metal CM5. In this case, the correcting unit 706 may correct the disposal position for the cut metal CM6 by, for example, moving the cut metal CM6 to a position on the cell frame 2000 in the border portion between the cells SC2 and SC3.

A procedure for a preparation process by the circuit designing device 501 is described next with reference to FIG. 21.

FIG. 21 is a flowchart depicting one example of the procedure for the preparation process by the circuit designing device 501. In the flowchart in FIG. 21, the circuit designing device 501 first generates the standard cell SC (step S2101). The standard cell SC is generated based on, for example, an operational input by a user (a designer) using an input device not depicted.

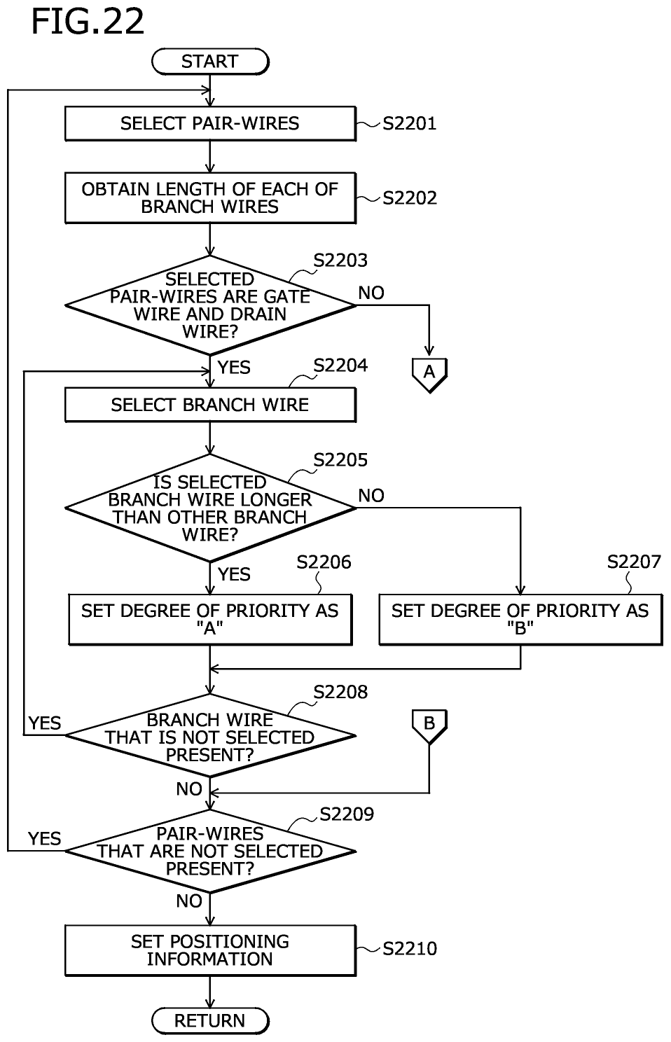

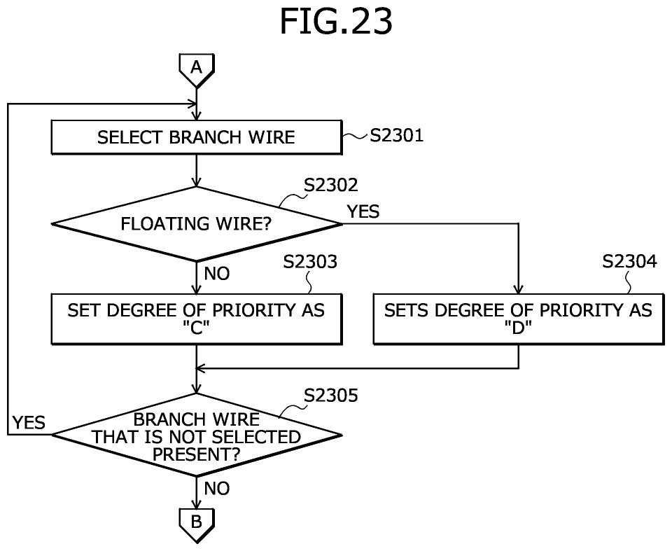

The circuit designing device 501 executes a positioning information setting process for the generated standard cell SC (step S2102). A detailed procedure for the positioning information setting process is described later with reference to FIG. 22 and FIG. 23.

Here, the details of the process procedure for the positioning information setting process are described with reference to FIG. 22 and FIG. 23. The circuit designing device 501 sets the degree of priority for each of the branch wires of each wire in the standard cell SC. For each branch wire having the degrees of priority redundantly set therefor, the circuit designing device 501 sets the degree of priority that is the higher one.

FIG. 22 and FIG. 23 are flowcharts depicting one example of the details of the process procedure for the positioning information setting process. In the flowchart in FIG. 22, the circuit designing device 501 selects unselected pair-wires that are not selected in the standard cell SC (step S2201). The pair-wires are a pair of adjacent wires in the standard cell SC.

The circuit designing device 501 next obtains the length of each of the branch wires included in the selected pair-wires (step S2202). The circuit designing device 501 determines whether the selected pair-wires are pair-wires of a gate wire and a drain wire (step S2203).

In a case where the circuit designing device 501 determines that the selected pair-wires are the pair-wires of a gate wire and a drain wire (step S2203: YES), the circuit designing device 501 selects an unselected branch wire that is not selected of the branch wires included in the selected pair-wires (step S2204). At this time, the circuit designing device 501 handles, for example, a branch wire included in the selected pair-wires (these pair-wires) as an unselected branch wire when the branch wire is not selected for these pair-wires even in a case where the branch wire is selected when the other of the pair-wires has been selected. The circuit designing device 501 determines whether the selected branch wire is longer than the other branch wire adjacent thereto of the selected pair-wires (step S2205).

In a case where the circuit designing device 501 determines that the selected branch wire is the longer branch wire (step S2205: YES), the circuit designing device 501 sets the degree of priority for the selected branch wire as “A” (step S2206) and moves to step S2208. On the other hand, in a case where the circuit designing device 501 determines that the selected branch wire is the shorter branch wire (step S2205: NO), the circuit designing device 501 sets the degree of priority as “B” for the selected branch wire (step S2207).

At step S2205, in a case where the length of the branch wire is equal to the length of the other branch wire, the circuit designing device 501 may set the degree of priority as “A” for the selected branch wire, or may set the degree of priority as “B” for the selected branch wire. At steps S2206 and S2207, in a case where the degree of priority is already set for the selected branch wire, the circuit designing device 501 sets the degree of priority that is the higher one of the set degrees of priority as the degree of priority of the selected branch wire.

The circuit designing device 501 next determines whether an unselected branch wire is present that is not selected of the branch wires included in the selected pair-wires (step S2208). In a case where the circuit designing device 501 determines that an unselected branch wire is present (step S2208: YES), the circuit designing device 501 returns to step S2204.

On the other hand, in a case where the circuit designing device 501 determines that no unselected branch wire is present (step S2208: NO), the circuit designing device 501 determines whether unselected pair-wires not selected in the standard cell SC are present (step S2209). In a case where the circuit designing device 501 determines that unselected pair-wires are present (step S2209: YES), the circuit designing device 501 returns to step S2201.

On the other hand, in a case where the circuit designing device 501 determines that no unselected pair-wires are present (step S2209: NO), the circuit designing device 501 sets the positioning information including the obtained length of the branch wire and the set degree of priority of the branch wire, for the standard cell SC (step S2210) and terminates the series of process steps of this flowchart.

At step S2203, in a case where the circuit designing device 501 determines that the selected pair-wires are not the pair-wires of a gate wire and a drain wire (step S2203: NO), the circuit designing device 501 moves to step S2301 depicted in FIG. 23.

In the flowchart in FIG. 23, the circuit designing device 501 selects an unselected branch wire that is not selected of the branch wires included in the selected pair-wires (step S2301). At this time, the circuit designing device 501 handles, for example, a branch wire included in the selected pair-wires (these pair-wires) as an unselected branch wire when the branch wire is not selected for these pair-wires even in a case where the branch wire is selected when the other of the pair-wires has been selected. The circuit designing device 501 determines whether the selected branch wire is a floating wire (step S2302).

In a case where the circuit designing device 501 determines that the selected branch wire is not a floating wire (step S2302: NO), the circuit designing device 501 sets the degree of priority as “C” for the selected branch wire (step S2303) and moves to step S2305. On the other hand, in a case where the circuit designing device 501 determines that the selected branch wire is a floating wire (step S2302: YES), the circuit designing device 501 sets the degree of priority as “D” for the selected branch wire (step S2304). At each of steps S2303 and S2304, in a case where the degree of priority is already set for the selected branch wire, the circuit designing device 501 sets the degree of priority that is the higher one of the set degrees of priority as the degree of priority of the selected branch wire.

The circuit designing device 501 next determines whether an unselected branch wire is present that is not selected of the branch wires included in the selected pair-wires (step S2305). In a case where the circuit designing device 501 determines that an unselected branch wire is present (step S2305: YES), the circuit designing device 501 returns to step S2301.

On the other hand, in a case where the circuit designing device 501 determines that no unselected branch wire is present (step S2305: NO), the circuit designing device 501 moves to step S2209 depicted in FIG. 22.

The circuit designing device 501 may thereby set the positioning information to determine the disposal number and the disposal positions of the cut metals, for the standard cell SC.

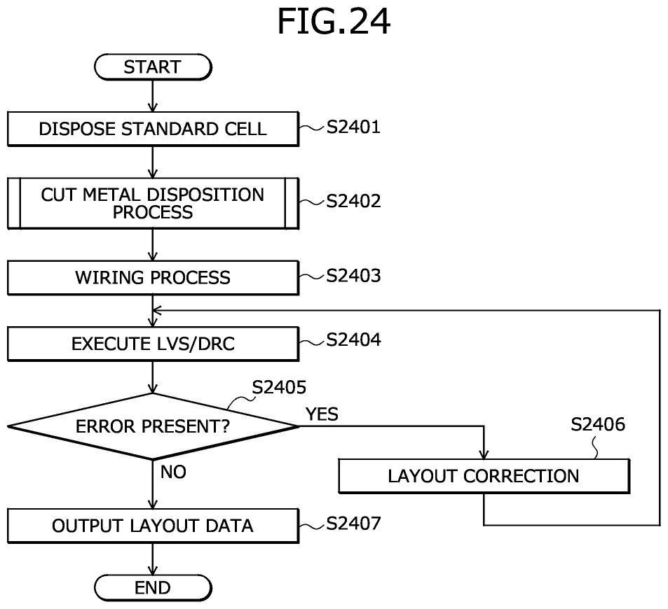

A procedure for a circuit design process by the circuit designing device 501 is described next with reference to FIG. 24.

FIG. 24 is a flowchart depicting one example of the procedure for the circuit design process by the circuit designing device 501. In the flowchart in FIG. 24, the circuit designing device 501 first disposes the standard cell SC in the layout of the circuit under design based on the circuit information related to the circuit under design (step S2401).

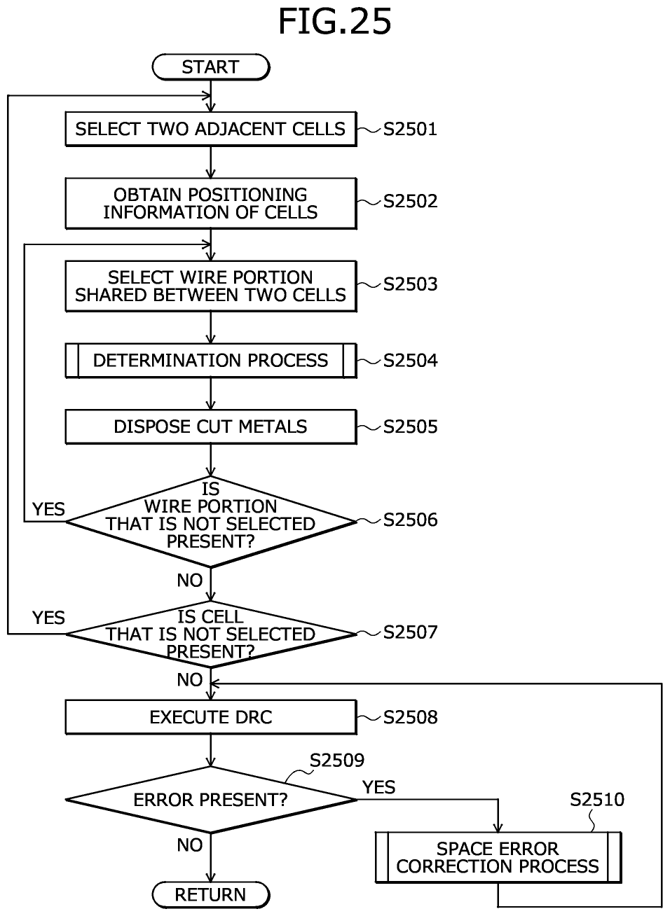

The circuit designing device 501 next executes a cut metal disposition process (step S2402). A detailed process procedure for the cut metal disposition process is described later with reference to FIG. 25.

The circuit designing device 501 executes a wiring process based on the circuit information related to the circuit under design (step S2403). The circuit designing device 501 next executes LVS/DRC for the circuit under design after the wiring process (step S2404). The circuit designing device 501 determines whether any error is present (step S2405).

In a case where the circuit designing device 501 determines that an error is present (step S2405: YES), the circuit designing device 501 executes layout correction (step S2406) and returns to step S2404. On the other hand, in a case where the circuit designing device 501 determines that no error is present (step S2405: NO), the circuit designing device 501 outputs the layout data that relates to the circuit under design (step S2407) and terminates the series of processes of this flowchart.

The circuit designing device 501 may thereby output, for the circuit under design, layout data that reduces the inter-wire capacitance that is the cause of a delay and an increase of the electric power while suppressing occurrence of space error between the cut metals.

A detailed process procedure for the cut metal disposition process at step S2402 is described next with reference to FIG. 25. The standard cell SC is denoted by “cell SC”.

FIG. 25 is a flowchart depicting one example of the details of the process procedure for the cut metal disposition process. In the flowchart in FIG. 25, the circuit designing device 501 first selects two adjacent cells SC of the cells SC disposed in the layout of the circuit under design (step S2501).

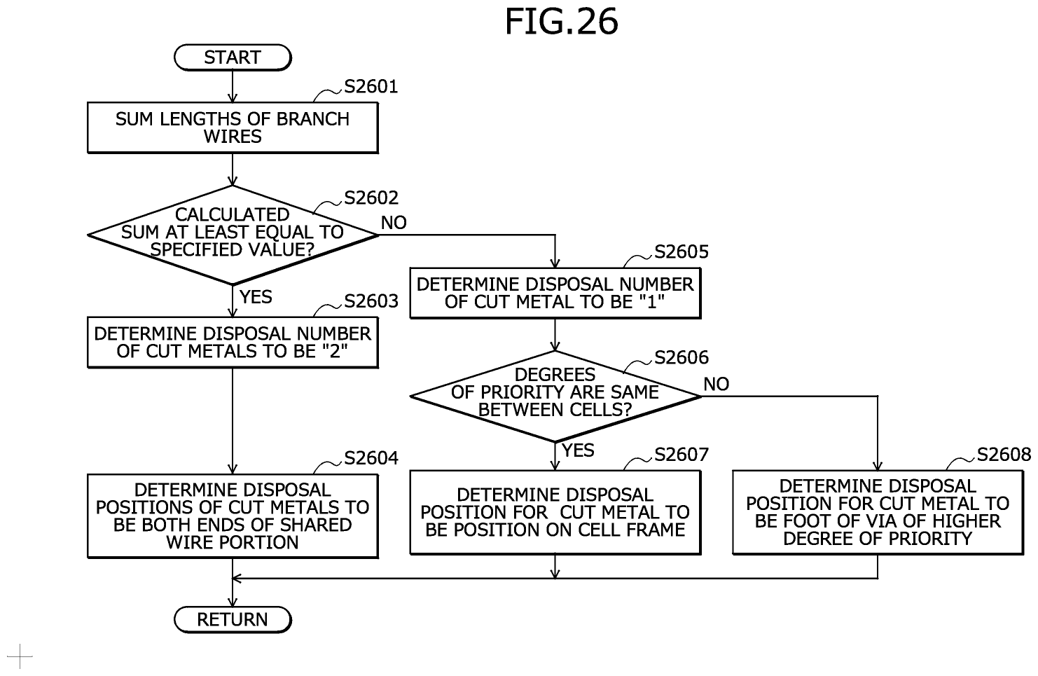

The circuit designing device 501 obtains the positioning information of the selected cells SC from the cell library LB (step S2502). The circuit designing device 501 next selects an unselected wire portion that is not selected of the wire portions shared between the two cells SC (step S2503). The circuit designing device 501 executes a determination process of determining the disposal number and the disposal positions of the cut metals to be disposed on the selected wire portion, based on the obtained positioning information of the cells SC (step S2504). A detailed process procedure for the determination process is described later with reference to FIG. 26.

The circuit designing device 501 next disposes the cut metals of the determined disposal number at the determined disposal positions (step S2505). The circuit designing device 501 determines whether an unselected wire portion is present that is not selected of the wire portions shared between the two cells SC (step S2506).

In a case where the circuit designing device 501 determines that an unselected wire portion is present (step S2506: YES), the circuit designing device 501 returns to step S2503. On the other hand, in a case where the circuit designing device 501 determines that no unselected wire portion is present (step S2506: NO), the circuit designing device 501 determines whether an unselected cell SC is present that is not selected of the cells SC disposed in the layout of the circuit under design (step S2507).

In a case where the circuit designing device 501 determines that an unselected cell SC is present (step S2507: YES), the circuit designing device 501 returns to step S2501. On the other hand, in a case where the circuit designing device 501 determines that no unselected cell SC is present (step S2507: NO), the circuit designing device 501 executes DRC for the disposed cut metals (step S2508).

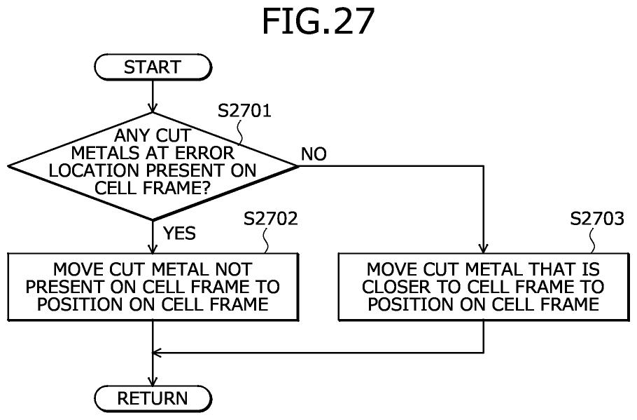

The circuit designing device 501 determines whether an error is present (step S2509). In a case where the circuit designing device 501 determines that an error is present (step S2509: YES), the circuit designing device 501 executes a space error correction process (step S2510) and returns to step S2508. A detailed process procedure for the space error correction process is described later with reference to FIG. 27.

On the other hand, in a case where the circuit designing device 501 determines that no error is present (step S2509: NO), the circuit designing device 501 returns to the step at which the cut metal disposition process is invoked.

The circuit designing device 501 may thereby determine the disposal positions of the cut metals to separate the signals from each other between the two adjacent cells SC.

A detailed process procedure for the determination process at step S2504 is described next with reference to FIG. 26.

FIG. 26 is a flowchart depicting one example of the details of the process procedure for the determination process. In the flowchart in FIG. 26, the circuit designing device 501 first sums the lengths of the branch wires that form the selected wire portion (step S2601). The circuit designing device 501 determines whether the calculated sum of the lengths of the branch wires is at least equal to a specified value (step S2602).

In a case where the circuit designing device 501 determines that the calculated sum is at least equal to the specified value (step S2602: YES), the circuit designing device 501 determines the disposal number of the cut metals to be disposed on the selected wire portion to be “2” (step S2603). The circuit designing device 501 determines the disposal positions of the cut metals to be both ends of the wire portion shared between the two selected cells SC (step S2604) and returns to the step at which the determination process is invoked.

At step S2602, in a case where the circuit designing device 501 determines that the calculated sum is smaller than the specified value (step S2602: NO), the circuit designing device 501 determines the disposal number of the cut metal to be disposed on the selected wire portion to be “1” (step S2605). The circuit designing device 501 next determines whether the degrees of priority of the branch wires that form the selected wire portion are equal to each other (step S2606).

In a case where the circuit designing device 501 determines that the degrees of priority are equal to each other (step S2606: YES), the circuit designing device 501 determines the disposal position for the cut metal to be a position on the cell frame of the selected wire portion (step S2607) and returns to the step at which the determination process is invoked.

On the other hand, in a case where the circuit designing device 501 determines that the degrees of priority are different from each other (step S2606: NO), the circuit designing device 501 determines the disposal position for the cut metal to be the foot of a via on the side of the branch wire whose degree of priority is the higher one, of the selected wire portions (step S2608) and returns to the step at which the determination process is invoked.

The circuit designing device 501 may thereby determine efficient disposal positions of the cut metals, capable of reducing the inter-wire capacitance and suppressing an occurrence of space error between the cut metals.

A detailed process procedure for the space error correction process at step S2510 is described next with reference to FIG. 27.

FIG. 27 is a flowchart depicting one example of the details of the process procedure for the space error correction process. In the flowchart in FIG. 27, the circuit designing device 501 first determines whether any of the cut metals at the error location is present on the cell frame (step S2701).

In a case where the circuit designing device 501 determines that one of the cut metals is present on the cell frame (step S2701: YES), the circuit designing device 501, of the two cut metals for which the space error occurs, moves the cut metal not present on the cell frame to a position on the cell frame (step S2702) and returns to the step at which the space error correction process is invoked.

On the other hand, in a case where the circuit designing device 501 determines that none of the cut metals is present on the cell frame (step S2701: NO), the circuit designing device 501, of the two cut metals for which the space error occurs, moves the cut metal that is closer to the cell frame to a position on the cell frame (step S2703) and returns to the step at which the space error correction process is invoked.

The circuit designing device 501 may thereby correct the disposal positions of the cut metals such that the space error is resolved.

As described above, according to the circuit designing device 501 of the second embodiment, the cells SC may be disposed in the layout of the circuit under design based on the circuit information related to the circuit under design. According to the circuit designing device 501, for two adjacent cells SC of the cells SC disposed in the layout, the disposal number and the disposal positions of the cut metals to be disposed between the two cells SC may be determined based on the length of a branch wire and the type of the wire that includes the branch wire.

The circuit designing device 501, in designing the layout using the multi-patterning technique, may thereby determine efficient disposal positions of the cut metals, capable of reducing inter-wire capacitance (parasitic capacitance) and suppressing occurrence of space error between the cut metals.

According to the circuit designing device 501, for two cells SC, the length of the wire portion shared between the two cells SC may be calculated based on the length of the branch wire, and the disposal number and the disposal positions of the cut metals to be disposed on the shared wire portion may be determined based on the calculated length of the shared wire portion and the type of the wire. The cells SC are each a standard cell that has no cut metal disposed on the cell frame thereof.

The circuit designing device 501 may thereby determine the disposal number and the disposal positions of the cut metals to be disposed on the shared wire portion, by taking into consideration the length of the wire portion shared between the two adjacent cells SC and the type of the wire. The circuit designing device 501 may increase the degree of priority of the disposition of the cut metals by determining the disposal positions from the wire portion shared between the cells SC after the cells are disposed.

According to the circuit designing device 501, for the cell SC, for each branch wire between a via on a wire in the cell SC and a cell frame, the degree of priority according to the type of the wire that includes the branch wire may be set. According to the circuit designing device 501, the disposal number and the disposal positions of the cut metals to be disposed on the shared wire portion may be determined based on the calculated length of the shared wire portion and the degree of priority set for each of the branch wires that form the shared wire portion.

The circuit designing device 501 may thereby set the degree of priority for each of the branch wires in the cell SC, by taking into consideration the degree of the influence on the Miller effect. It may be stated that a branch wire whose degree of priority is higher is a point whose effect of reducing the inter-wire capacitance by shortening the length of the adjacent wire is more significant.

According to the circuit designing device 501, in a case where pair-wires of a wire including an object branch wire in the cell SC and another wire adjacent to the wire are pair-wires of a gate wire and a drain wire, a degree of priority higher than those of the branch wires in other pairs may be set for the object branch wire. The object branch wire is a branch wire to have the degree of priority set therefor.

The circuit designing device 501 may thereby set the degree of priority for each of the branch wires in the cell SC, by taking into consideration that a point at which a gate wire and a drain wire are adjacent to each other receives a heavier influence of the Miller effect, than that on the point at which an internal wire or a floating wire is adjacent.

According to the circuit designing device 501, in a case where the length of the object branch wire is longer than the length of another branch wire included in another wire, a degree of priority higher than that of the other branch wire may be set for the object branch wire.

The circuit designing device 501 may thereby set the degree of priority for each of the branch wires in the cell SC, by taking into consideration that the inter-wire capacitance increases in proportion to the adjacency length between the gate wire and a drain wire.

According to the circuit designing device 501, in a case where the pair-wires are pair-wires of a floating wire and a wire other than a floating wire and a wire including the object branch wire is a wire other than a floating wire, a degree of priority higher than those of the other branch wires included in the other wires may be set for the object branch wire.

The circuit designing device 501 may thereby set the degree of priority for each of the branch wires in the cell SC, by taking into consideration that inter-wire capacitance other than that caused by the Miller effect occurs, in a case of wires each having a signal present therein even at a point other than the point at which a gate wire and a drain wire are adjacent to each other.

According to the circuit designing device 501, in a case where the length of the shared wire portion is smaller than a specified value, the disposal number of the cut metal to be disposed on the shared wire portion may be determined to be “1” and the disposal position for the cut metal may be determined to be one point based on the degree of priority set for each of the branch wires.

The circuit designing device 501 may thereby suppress occurrence of space error between the cut metals. The circuit designing device 501 may determine the disposal positions of the cut metals such that the effect of reducing the inter-wire capacitance by shortening the lengths of adjacent wires is enhanced.

According to the circuit designing device 501, in a case where the length of the shared wire portion is at least equal to the specified value, the disposal number of the cut metals to be disposed on the shared wire portion may be determined to be “2” and the disposal positions of the cut metals may be determined to be both ends of the shared wire portion.

The circuit designing device 501 may thereby enhance the effect of reducing the inter-wire capacitance by minimizing the length of the adjacent wires, by determining the feet of both vias as the disposal positions of the cut metals, when a distance preventing an occurrence of space error may be secured.

According to the circuit designing device 501, the cut metals of the determined disposal number may be disposed at the determined disposal positions.

The circuit designing device 501 may thereby dispose the cut metals at the positions capable of reducing the inter-wire capacitance suppressing occurrence of any space error between the cut metals.

According to the circuit designing device 501, layout data may be output that relates to the circuit under design that has therein the cut metals of the determined disposal number disposed at the determined disposal positions.

The circuit designing device 501 may thereby output, for the circuit under design, layout data that reduces the inter-wire capacitance that is the cause of delay and increase of the electric power and that suppresses an occurrence of space error between the cut metals.

According to the circuit designing device 501, in a case where the cut metals of the determined disposal number are disposed at the disposal positions and, as a result, a space error occurs, the disposal position for at least any one cut metal at the point at which the space error occurs may be moved to a position on the cell frame, in the border portion between the two cells SC.

In a case where an error occurs in the vertical direction, the circuit designing device 501 may thereby suppress an occurrence of a space error by securing the distance between the cut metals or forming one cut metal on the cell frame, by moving the cut metal.

As described above, according to the circuit designing device 501, in a semiconductor integrated circuit using wires by the multi-patterning technique, the inter-wire capacitance may be reduced, the Miller effect may be suppressed, and delay and the electric power may be reduced, by placing a cut metal at a position with which the effect of reducing the inter-wire capacitance generated in a wire not used in the wire connection (a branch wire) is high.

For example, to minimize the adjacency length between the wires of a gate wire and a drain wire for which the capacity seems to be larger than in actuality due to the Miller effect of the wires used as signal wires, the circuit designing device 501 may cut off the branch wire present between a via and a cell frame without causing any space error to occur between the cut metals. The circuit designing device 501 may thereby reduce, with priority, the inter-wire capacitance between the gate wire and a drain wire, which are the cause of the Miller effect, and may reduce delay and electric power.

The design aiding method described in the present embodiment may be implemented by executing a prepared program on a computer such as a personal computer and a workstation. The program is stored on a non-transitory, computer-readable recording medium such as a hard disk, a flexible disk, a CD-ROM, a DVD, a USB memory, etc. read out from the computer-readable medium, and executed by the computer. The design aiding program may be distributed through a network such as the Internet.

The information processing device 101 (circuit designing device 501) described in the present embodiment can be realized by an application specific integrated circuit (ASIC) such as a standard cell or a structured ASIC, or a programmable logic device (PLD) such as a field-programmable gate array (FPGA).

According to an aspect of the present invention, an effect is achieved that an inter-wire capacitance due to a wire not used in the wire connection may be suppressed.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A computer-readable recording medium storing therein a design aiding program that aids layout design of a circuit under design and that is executable by a computer, the design aiding program comprising:
an instruction for disposing a plurality of cells in a layout of the circuit under design, based on circuit information related to the circuit under design; and
an instruction for determining, for two adjacent cells of the cells disposed in the layout, a disposal number and disposal positions of cut metals to be disposed between the two adjacent cells, based on lengths of branch wires in each of the two adjacent cells and a type of a wire that includes the branch wires, each of the lengths being between a via and a cell frame of said each of the two adjacent cells, the via being on the wire in the two adjacent cells.

2. The recording medium according to claim 1, wherein
the cells are each a standard cell that has no cut metal disposed on the cell frame thereof,
the design aiding program further comprises an instruction for calculating, for the two adjacent cells, a length of a wire portion shared between the two adjacent cells, based on the lengths of the branch wires, and
the disposal number and the disposal positions of the cut metals to be disposed on the shared wire portion are determined based on the calculated length of the shared wire portion and the type of the wire.

3. The recording medium according to claim 2, the design aiding program further comprising
an instruction for setting, for each of the cells, a degree of priority for each of the branch wires between a via on a wire in said each of the cells and the cell frame of said each of the cells, according to the type of the wire that includes said each of the branch wires, wherein
the disposal number and the disposal positions of the cut metals to be disposed on the shared wire portion are determined based on the length of the shared wire portion and the degree of priority set for said each of the branch wires forming the shared wire portion.

4. The recording medium according to claim 3, wherein
the type of the wire indicates any one of a gate wire, a drain wire, an internal wire, and a floating wire, and
when a pair including the wire that includes said each of the branch wires in said each of the cells and another wire adjacent to the wire is a pair including the gate wire and the drain wire, a degree of priority higher than those of branch wires in other pairs is set for said each of the branch wires.

5. The recording medium according to claim 4, wherein
when the length of said each of the branch wires is longer than lengths of the other branch wires included in the other wires, a degree of priority higher than those of the other branch wires is set for said each of the branch wires.

6. The recording medium according to claim 4, wherein
when the pair is a pair including the floating wire and a wire other than the floating wire and the wire that includes the branch wire is a wire other than the floating wire, a degree of priority higher than those of the other branch wires included the other wires is set for said each of the branch wires.

7. The recording medium according to claim 3, wherein
when the length of the shared wire portion is smaller than a specified value, the disposal number of the cut metal to be disposed on the shared wire portion is determined to be “1”, and
the disposal position for the cut metal is determined to be one point based on the degrees of priority set for the branch wires.

8. The recording medium according to claim 7, wherein
when the length of the shared wire portion is at least equal to the specified value, the disposal number of the cut metals to be disposed on the shared wire portion is determined to be “2”, and
the disposal positions of the cut metals are determined to be both ends of the shared wire portion.

9. The recording medium according to claim 3, the design aiding program further comprising
an instruction for disposing the cut metals of the determined disposal number at the determined disposal positions.

10. The recording medium according to claim 9, the design aiding program further comprising
an instruction for outputting layout data related to the circuit under design that has the cut metals of the determined disposal number disposed at the determined disposal positions.

11. The recording medium according to claim 9, wherein
when a space error occurs as a result of disposing the cut metals of the disposal number at the disposal positions, the disposal position for at least any one of the cut metals at a point at which the space error occurs is moved to a position on the cell frame in a border portion between the two adjacent cells.

12. A computer-implemented design aiding method that aids layout design of a circuit under design and that is executable by a computer, the design aiding method comprising:
disposing a plurality of cells in a layout of the circuit under design, based on circuit information related to the circuit under design; and
determining, for two adjacent cells of the cells disposed in the layout, a disposal number and disposal positions of cut metals to be disposed between the two adjacent cells, based on lengths of branch wires in each of the two adjacent cells and a type of a wire that includes the branch wires, each of the lengths being between a via and a cell frame of said each of the two adjacent cells, the via being on the wire in the two adjacent cells.

13. An information processing device that aids layout design of a circuit under design and that is executable by a computer, the information processing device comprising:
a memory; and
a processor coupled to the memory, the processor configured to:
dispose a plurality of cells in a layout of the circuit under design, based on circuit information related to the circuit under design; and
determine, for two adjacent cells of the cells disposed in the layout, a disposal number and disposal positions of cut metals to be disposed between the two adjacent cells, based on lengths of branch wires in each of the two adjacent cells and a type of a wire that includes the branch wires, each of the lengths being between a via and a cell frame of said each of the two adjacent cells, the via being on the wire in the two adjacent cells.
